(19) United States
(12) Patent Application Publication
(10) Pub. No.: US 2021/0296120 A1
(43) Pub. Date: Sep. 23, 2021

(54) Method of filling high aspect ratio, small dimension gaps and formulations useful therein

(71) Applicants: Kenneth L. Foster, Midland, MI (US); James P. GODSCHALX, Midland, MI (US); Michael G. SIMMONDS, Genval (BE)

(72) Inventors: Kenneth L. Foster, Midland, MI (US); James P. GODSCHALX, Midland, MI (US); Michael G. SIMMONDS, Genval (BE)

(21) Appl. No.: 10/552,877

(22) PCT Filed: Apr. 15, 2004
(86) PCT No.: PCT/US2004/011534

§ 371 Date: Oct. 12, 2007

Related U.S. Application Data
(60) Provisional application No. 60/463,709, filed on Apr. 17, 2003.

(51) Int. Cl. H01L 21/02; H01L 21/762; B05D 3/02; C08L 79/08; C08L 61/18; C08G 10/00; C09D 179/08; C09D 161/18

(52) U.S. Cl. CPC H01L 21/02282; H01L 21/76224; H01L 21/02118; B05D 3/0254; C09D 161/18; C08L 61/18; C08G 10/00; C09D 179/08; C08L 79/08

(57) ABSTRACT

The invention is a method comprising (a) providing a substrate having at least one recessed feature characterized by a width of less than about 0.3 microns and an aspect ratio of 5 or higher, (b) coating onto the substrate a composition comprising (i) a curable polymeric material, (ii) a thermally deactivatable gap-filling aid, and (iii) at least one solvent, (c) drying the coated substrate to remove the solvent, leaving a composition of cross-linkable polymeric material and gap-filling aid substantially filling the recessed feature, and (d) heating the coated substrate to cure the polymeric material and to de-activate the gap-filling aid, wherein the cured material has a glass transition temperature of no less than 300° C. and, preferably, a thermal stability temperature of at least 300° C.

### FIELD OF THE INVENTION

This invention relates to a method and formulation useful in filling high aspect ratio, small dimension gaps during microelectronics manufacture.

### BACKGROUND OF THE INVENTION

In microelectronics manufacture, it is common that features, such as trenches, vias or holes are formed and need to be filled with various materials. These features are characterized in one aspect by their aspect ratio—i.e—the ratio of height or depth of the feature to the smallest dimension of width or length. There are various situations where very high aspect ratio features (e.g. aspect ratios of 10 or higher) with very small widths or gaps need to be filled with a material. For example, U.S. Pat. No. 6,458,647 teaches a method of making deep trenches for use in DRAM memory cells. In the process of manufacture a sacrificial, non-specified resist material fills a significant portion of the trench up to a pre-specified level. Other applications where high aspect ratio features may need to be filled with a dielectric material include stacked capacitors, certain subtractive integration schemes of interlayer dielectrics where high aspect ratios (e.g. >5:1) may be used, self-aligned contacts in active devices, pre-metal dielectrics, etc. See also the following examples of integration methods where a material needs to fill an underlying topography. As technology advances one or more of these methods may require fill of high aspect ratio features. e.g. U.S. Pat. No. 6,352,591; Mouloud Baldi, Lauerence Baud, Hichem M'Saad, Didier Pique, Patrick Rabinzohn, “Materials and Processing for 0.25 micron Multilevel Interconnect,” Microelectronic Engineering 33, (1997) 175-188; W. C. Gau, T. C. Chang, Y. S. Lin, J. C. Hu, L. J. Chen, C. Y. Chang, C. L. Cheng, “Copper electroplating for future ultralarge scale integration interconnection,” J. Vac. Sci. Technology. A 18(2), March/April 2000; John Baliga, “Options for CVD of Dielectrics Include Low-K Materials,” Semiconductor International, Volume 21, No. 6, June 1998; Juseon Goo, Eunke Hong, Hong-gun Kim, Hyun Jo Kim, et. al. “A Highly Manufacturable, Low-Thermal Budget, Void and Seam Free Pre-Metal Dielectric Process Using new SOG for beyond 60 nm DRAM and other devices,” International Electronic Device Manufactures (IEDM), session 12 paper 03, December 2001; Jin-Hwa Heo, Soo-Jin Hong, Dong-Ho Ahn, Hyun-Duk Cho, Moon-Han Park, Kazuyuki Fujihara, et. al., “Void Free and Low Stress Shallow Trench Isolation Technology using P-SOG for sub 0.1 micron Device,” Symposium on VLSI section 14.1, June 2002. While some of these applications have required processing temperatures of 700 to 1000° C., recent efforts to reduce the thermal budget are reducing these processing temperatures.

Finding materials that can be used for filling such high aspect ratio features is challenging. For uniform and consistent manufacture, the recessed features need to be completely filled and consistent, without voids. If the gap filling properties of the material being used to fill the gap is poor, one may encounter bridging with underlying voids within the recessed feature leading to non-uniform properties (e.g etch selectivity, dielectric constant, breakdown voltage, reliability, etc.). Finding suitable materials becomes even more difficult when other properties such as thermal stability, desired etch selectivity, dielectric properties, ease of use and the like are considered.

U.S. Pat. No. 5,965,679 disclosed a class of polyarylene materials that have good thermal stability for back end of the line interlayer dielectric applications and very good electrically insulative properties. These materials were disclosed as being useful in filling moderate aspect ratio features (aspect ratios of about 2) by solvent coating.

Thus, a need remains for a system using solvent-coatable, thermally-stable materials to fill very small, high aspect ratio features for various microelectronics applications.

### SUMMARY OF THE INVENTION

Applicants have discovered a method of filling very small, high aspect ratio features with thermally stable, polymeric materials via solvent coating.

This method comprises:

(a) providing a substrate having at least one recessed feature characterized by a width of less than about 0.3 microns and an aspect ratio of 5 or higher,

(b) coating onto the substrate a composition comprising (i) a curable polymeric material, (ii) a thermally deactivatable gap-filling aid, and (iii) at least one solvent,

(c) drying the coated substrate to remove the solvent, leaving a composition of cross-linkable polymeric material and gap-filling aid substantially filling the recessed feature,

(d) heating the coated substrate to cure the polymeric material and to de-activate the gap-filling aid, wherein the cured material has a glass transition temperature of no less than 300° C. and, preferably, a thermal stability temperature of at least 300° C.

As used herein thermal stability temperature means the maximum temperature, T, at which the weight loss of a sample maintained at that temperature in an inert environment is less than 1 percent per hour.

### DETAILED DESCRIPTION OF THE INVENTION

Any substrate having recessed features of small dimension and high aspect ratio may be used in this invention. As the primary intended use of this method is in microelectronics manufacture, particularly useful substrates comprise semiconductor materials such as silicon and gallium arsenide. The substrate may also include other semiconductor elements such as transistors or diodes. However, other substrates having recessed features of small dimension and high aspect ratio may also be used as desired.

The recessed features are such things as gaps, holes, vias, trenches and the like where the depth of the feature is large relative to the width of the feature. The depth of the feature is the distance from surface of the substrate at the opening of the feature to a point at the bottom of the feature. The width as used herein is the narrowest distance across the opening of the feature at the surface of the substrate.

Preferably, the method of this invention is used on substrates having recessed features with widths of 0.3 microns or less, more preferably 0.25 microns or less, more preferably still 0.2 microns or less, and most preferably 0.1 microns or less. Preferably, the aspect ratio (depth/width) of the recessed feature is about 5 or more, more preferably 10 or more, and most preferably 20 or more.

The composition coated onto the substrate comprises solvent and thus, the composition is conveniently applied by known solvent coating and printing methods such as spin coating, dip coating, ink jet printing, etc. The composition comprises a curable polymer. The curable polymer is susceptible to further reaction, preferably cross-linking, to enhance the thermal stability of the cured polymer relative to the uncured polymer. Preferably, the glass transition temperature of the cured polymer is greater than 350° C., more preferably greater than 400° C. The thermal stability temperature of the cured polymer is preferably greater than 300° C., more preferably greater than 400° C., more preferably still greater than 450° C. For applications where the cured polymer remains part of the device, preferably the cured polymer has a dielectric constant of less than about 3.5, more preferably less than about 3.0.

Preferably, the curable polymer is organic. By organic polymer is meant a polymer that comprises primarily carbon atoms in the polymer backbone although the polymers may also have other atoms such as oxygen, nitrogen, and the like in the polymer backbone. The organic polymers contain few or no Silicon atoms. These organic polymer materials have excellent etch selectivity relative to the inorganic materials (e.g. silicon oxide, silicon nitride, etc.) that are frequently also used in microelectronics manufacture and this facilitates patterning and formation of various features in the microelectronic article. The number average molecular weight of the curable polymer is preferably greater than about 3,000, more preferably greater than about 4,000. The number average molecular weight of the curable polymer is preferably less than about 20,000, more preferably no greater than about 15,000, more preferably no greater than about 10,000, and most preferably no greater than about 7,000.

Alternatively, the curable polymer may be an inorganic polymer such as the spin-on glass materials known in the industry. Examples of such inorganic polymers include silsesquioxanes such as hydrogen silsesquioxanes, methyl silsesquioxane, and the like.

Non-limiting examples of suitable organic polymers include polyarylenes, polyarylene ethers, polyimides, polybenzoxazoles, polynorbomenes, polynaphthalenes, polybenzocyclobutenes, polyperfluorocyclobutenes, polyphenylquinoxalines, and polybenzimidazoles and their derivatives or copolymers of these species. These polymers are characterized by residual unreacted groups from the monomers or by other reactive groups incorporated into the polymer as pendant groups, terminal groups, and/or functional groups within the backbone of the polymer. The presence of these reactive groups enables further reaction of the polymer after coating to increase the molecular weight of the polymer and preferably to form a cross-linked polymer.

Polyarylene and polyarylene ethers are the preferred materials. The functional reactive groups preferably are groups that react by Diels Alder reaction, but may be other groups that provide the necessary cross-linkability. Especially preferred reactive groups are dienes and dienophiles, such as cyclopentadienone and acetylene groups. However, acetylene/acetylene cross-linking reactions may also be used.

The most preferred polyarylene materials are the partially polymerized (i.e. B-staged) reaction products of multifunctional monomers having diene and dienophile groups. Preferably, at least some of the monomers have at least three functional groups to enable cross-linking and branching as well as chain extension reactions. A preferred diene group is a cyclopentadienone group. A preferred dienophile is an acetylene group. Examples of such polymers can be found in U.S. Pat. No. 5,965,679 and U.S. patent application Ser. No. 10/365,938.

In addition to the polymer, it is necessary that the composition include a gap filling aid that is thermally deactivatable. The purpose of the gap filling aid is to improve the ability of the polymer material to fill the high aspect ratio recessed features by modifying the rheological properties of the composition relative to a composition not containing the gap filling aid. In addition, the gap filling aid should not substantially impact the final properties of the organic polymer after curing of the polymer. Thus, a thermally deactivatable gap filling aid is used. The thermally deactivatable gap-filling aid is preferably selected from reactive monomers; reactive, low molecular weight oligomers (molecular weights preferably on the order of 1,500 or less, more preferably 1,000 or less); and low molecular weight thermally transient modifiers. The thermal transient modifiers may be low molecular weight (e.g. 2,000 or less, preferably 1,500 or less, more preferably 1,000 or less) compounds, including polymers or oligomers, that are preferably substantially compatible with the curable polymer, but that are thermally removable—e.g. by thermal degradation or volatilization and diffusion—at, near, or slightly below (e.g. up to 50° C. below, more preferably up to 30° C. below) the cure temperature of the curable polymer. By substantially compatible is meant that the gap fill aid does not substantially phase separate or aggregate such as to form pores or voids when removed from the curable or cured polymer. Preferably, the gap fill aid has a total Hansen solubility parameter, δₜ, that differs from the solubility parameter for the curable polymer or the cured polymer by less than 1, more preferably less than 0.5 MPa^{1/2}. For the preferred curable polymer, the total Hansen solubility parameter for the gap fill aid is in the range of about 21 to about 23 MPa^{1/2}. For further explanation of Hansen solubility parameters see, e.g., Hansen Solubility Parameter: A User's Handbook, Charles M. Hansen, CRC Press LLC, Boca Raton, Fla., 2000.

With the reactive monomers and low molecular weight reactive oligomers, the monomer or oligomer reacts with the polymer during cure and thus becomes a part of the final composition. The monomer or oligomer preferably is similar in chemical nature to the monomers used to form the organic polymer thus minimizing or eliminating any impact on final properties of the cured polymer. For example, for the more preferred polyarylene systems having diene and/or dienophile reactive groups, monomers or low molecular weight oligomers having aromatic functionality and diene and/or dienophile groups are useful. The aromatic functionality improves compatibility with the polymer while the diene and/or dienophile groups are reactive with the reactive groups on the polymer. Preferably, the polyarylenes contain unreacted diene groups (e.g. cyclopentadienone) and the gap filling additives are acetylene containing monomers. Non-limiting examples of suitable acetylene containing monomers include mono-substituted aromatic acetylenes, di-substituted aromatic acetylenes such as 4,4′-bis(phenylethynyl)diphenyl ether, tri-substituted aromatic acetylenes (e.g. trisethynylbenzenes, tris(phenylethynyl)benzenes, 2,4,4′-tris(phenylethynyl)diphenyl ether, 4′,4′,4′-tris(phenylethynyl)-1,3,5-triphenylbenzene, 3′,3′,3′-tris(phenylethynyl)-1,3,5-triphenylbenzene, etc.) and tetra-substituted aromatic acetylenes (e.g. 2,2-bis(3,4-di(phenylethynyl)phenyl)-1,1,1,3,3,3-hexafluoropropane). The low molecular weight oligomers used are preferably polyarylene or polyarylene ether oligomers having cyclopentadienone and/or acetylene functional groups.

Alternatively, low molecular weight oligomeric species that are compatible with both the solvent used and the organic polymer may be used as the gap filling aid. These oligomeric species, preferably, are such that they are thermally removable at or near the cure temperature for the organic polymer. Thus, they provide the desired modification in rheological properties without substantially impacting final properties of the cured organic polymer. Examples of such low molecular weight thermally transient modifiers include polystyrenes, polyacrylates, polymethacrylates, etc. Preferably the number average molecular weight of such materials is less than 7,000, more preferably less than 6,000, most preferably less than 5,000.

The composition also comprises a carrier solvent. The solvent can be any hydrocarbon based solvent in which the organic polymer and the gap filling aid are dispersible. Suitable solvents include mesitylene, pyridine, triethylamine, N-methylpyrrolidinone (NMP), methyl benzoate, ethyl benzoate, butyl benzoate, cyclopentanone, cyclohexanone, cycloheptanone, cyclooctanone, cyclohexylpyrrolidinone and ethers or hydroxy ethers (such as dibenzylethers, diglyme, triglyme, diethylene glycol ethyl ether, diethylene glycol methyl ether, dipropylene glycol methyl ether, dipropylene glycol dimethyl ether, propylene glycol phenyl ether, propylene glycol methyl ether, tripropylene glycol methyl ether), toluene, xylene, benzene, dipropylene glycol monomethyl ether acetate, dichlorobenzene, propylene carbonate, naphthalene, diphenyl ether, butyrolactone, dimethylacetamide, dimethylformamide, ethoxyethylpropionate, and mixtures thereof. The preferred solvents are mesitylene, N-methylpyrrolidinone (NMP), gamma-butyrolactone, diphenylether, cyclohexanone or mixtures of two or more of the preceding.

The components of the composition are present in amounts selected so as to give the desired thickness of the polymer on the substrate after coating while ensuring adequate amounts of gap-filling aid and solvent to ensure adequate gap fill. Preferably the amounts are as follows:

At least 5%, more preferably at least 10%, and most preferably 20% but no more than 40%, preferably no more than 35%, more preferably no more than 30% by weight of curable polymer based on total weight of the composition, and at least 1%, more preferably at least 3%, and most preferably at least 5% but no more than 20%, more preferably no more than 15%, most preferably no more than 10% by weight of gap-filling aid based on total weight of the composition. The remainder of the composition may comprise low volume additives such as adhesion promoters, antistatic agents, fillers, and the like, but is predominantly if not entirely the solvent system.

Use of solvent as a gap filling aid is not desirable because it may make attaining films of the desired thickness extremely difficult when relatively high thicknesses are needed. In addition, since the solvents tend to volatilize at a temperature well below the cure temperature of the polymer, rapid volatilization of trapped solvent during cure may lead to voids.

After application of the composition to the substrate the solvent is removed by drying. Some mild heating may be applied to accelerate the drying.

The coated article is then heated to a temperature sufficient to cure the organic polymer. During this heating step, if a reactive gap-filling aid was used, the aid reacts with the polymer and becomes part of the final product. If a transient, low molecular weight gap filling aid was used, the heating step is preferably gradual or occurs in two steps such that composition will first reflow as its glass transition temperature is reached, thereby filling in voids in the recessed features that occurred in the initial coating step. Then, cure and removal of the transient gap filling aid occurs at a higher temperature.

Other process steps can then be performed as desired. For example, other materials may be added above the cured organic polymer. Alternatively, the walls of the recessed feature above the cured polymer may be treated as for example in U.S. Pat. No. 6,458,647 followed by removal of the organic polymer by conventional etching methods.

The invention is further illustrated by the following examples which are not to be considered limiting of the scope of the invention.

### EXAMPLES

### Example 1—Synthesis of Curable Polyarylene

A polyarylene material is prepared according to the following procedure. Into a 2 liter round bottom flask is added:
445 g of gamma-butyrolactone solvent
200 g of 3,3′-(oxydi-1,4-phenylene)bis(2,4,5-triphenylcyclopentadienone)
96.7 g of 1,3,5-tris(phenylethynyl)benzene
Total=741.7 g with 60 wt. % solvent and 40 wt. % monomers

The reaction mixture is stirred to suspend the solids in the solvent. A water condenser is used to prevent loss of solvent at reaction temperatures and a nitrogen blanket is applied to prevent or limit oxidation. The reaction mixture is heated up to about 185° C. and held isothermally for about 27 hours. The solution is allowed to cool to about 90° C. at which time 247.2 g of mesitylene is added as a let down solvent. Final composition is about 30% reaction product (i.e. polymer with a number average molecular weight of about 4,000 as determined from Size Exclusion Chromatography) in solvent.

### Example 2: Control Experiment

About 82 grams of a composition made according to a process similar to that recited in Example 1 is, further diluted with about 18 grams of mesitylene. A small amount (about 2 to about 50 milliliters) of this formulation is dispensed onto an 8 inch silicon wafer which comprises 0.1 micron diameter holes etched a distance of about 7 microns deep into the substrate. The wafer is then spun at about 3,000 rpms, placed on a hotplate at about 320° C. for 90 seconds in nitrogen atmosphere and then cured in a nitrogen atmosphere in a furnace for about 30 minutes at 400° C.

The wafer is snap cleaved. Samples are mounted on aluminum stubs, coated with 30 angstroms of chromium and examined in a scanning electron microscope. The samples reveal poor gap fill of the 0.1 micron holes with large voids present at the bottom of the holes in the test structure.

### Example 3: Formulation of Polyarylene with Reactive Gap Filling Aid

About 24.5 grams of a polymer made according to a process as set forth in example 1 is obtained by precipitating the polymer in water, isolating precipitated solid by filtration, and drying. This polymer is combined with about 34 grams of gamma-butyrolactone, about 34 grams of mesitylene, and about 8 grams of a reactive coating aid (1,3,5-tris(phenylethynyl)benzene). This formulation is coated as described in Example 2. SEMs of the resultant samples reveal good gap fill without noticeable voids in the gaps.

### Example 4: Formulation of Polyarylene with Reactive Gap Filling Aid

About 24.5 grams of a polymer made according to a process as set forth in example 1 is obtained by precipitating the polymer in water, isolating precipitated solid by filtration, and drying. This polymer is combined with about 36 grams of gamma-butyrolactone, about 36 grams of mesitylene, and about 4 grams of a reactive coating aid (1,3,5-tris(phenylethynyl)benzene). This formulation is coated as described in Example 2. SEMs of the resultant samples reveal good gap fill without noticeable voids in the gaps.

### Example 5: Formulation of Polyarylene with Polystyrene Filling Aid

About 24.5 grams of a polymer made according to a process as set forth in example 1 is obtained by precipitating the polymer in water, isolating precipitated solid by filtration, and drying. This polymer is combined with about 34 grams of gamma-butyrolactone, about 34 grams of mesitylene, and about 8 grams of a 6,000 Mn monodisperse polystyrene. This formulation is coated as described in Example 2. SEMs of the resultant samples reveal good gap fill without noticeable voids in the gaps.

### Example 6: Formulation of Polyarylene with Polyacrylate Filling Aid

About 24.5 grams of a polymer made according to a process as set forth in example 1 is obtained by precipitating the polymer in water, isolating precipitated solid by filtration, and drying. This polymer is combined with about 35 grams of gamma-butyrolactone, about 35 grams of mesitylene, and about 6 grams of less than 7,000 Mn monodisperse polyacrylate. This formulation is coated as described in Example 2. SEMs of the resultant samples are expected to reveal good gap fill without noticeable voids in the gaps.

### Example 7: Gap Filling Additive of Oligomer—Synthesis of Curable Polyarylene Oligomer Additive

A polyarylene oligomer is prepared according to the following procedure. Into a 2 liter round bottom flask is added:
445 g of gamma-butyrolactone solvent
200 g of 3,3′-(oxydi-1,4-phenylene)bis(2,4,5-triphenylcyclopentadienone)
96.7 g of 1,3,5-tris(phenylethynyl)benzene
Total=741.7 g with 60 wt. % solvent and 40 wt. % monomers

The reaction mixture is stirred to suspend the solids in the solvent. A water condenser is used to prevent loss of solvent at reaction temperatures and a nitrogen blanket is applied to prevent or limit oxidation. The reaction mixture is heated up to about 195° C. and held isothermally for about 5.5 hours. Solution is allowed to cool to about 90° C. at which time 247.2 g of mesitylene is added as a let down solvent. Final composition is about 30% reaction product (i.e. oligomer should have a number average molecular weight of about 1,840 or less as determined from Size Exclusion Chromatography) in solvent. The additive is obtained by precipitating the oligomer in water and drying.

### Example 8: Formulation of Polyarylene with Oligomer Reactive Gap Filling Aid

About 24.5 grams of a polymer made according to a process as set forth in example 1 is obtained by precipitating the polymer in water and drying. This polymer is combined with about 34 grams of gamma-butyrolactone, about 34 grams of mesitylene, and about 8 grams of a reactive coating oligomer from example 7. This formulation is coated as described in Example 2. SEMs of the result are expected to reveal good gap fill without noticeable voids in the gaps.

### Example 9: Polyimide Formulation with Thermally Transient Gap Filling Aid

A polymeric precursor to a polyimide (e.g. poly(amic acid) or poly(amic ester)) is combined with a low molecular weight acrylate oligomer in a solvent. This solution may be coated on a substrate as described in Example 2. The composition may then be reacted under heating to form the polyimide and remove the acrylate oligomer. The presence of the low molecular weight acrylate oligomer is anticipated to improve the gap fill properties of the formulation when compared to the formulation without such an oligomer.

What is claimed is:

1. A method comprising:
(a) providing a substrate having at least one recessed feature characterized by a width of less than about 0.3 microns and an aspect ratio of 5 or higher,
(b) coating onto the substrate a composition comprising (i) a curable polymeric material, (ii) a thermally deactivatable gap-filling aid, and (iii) at least one solvent,
(c) drying the coated substrate to remove the solvent, leaving a composition of curable polymeric material and gap-filling aid substantially filling the recessed feature,
(d) heating the coated substrate to cure the polymeric material and to de-activate the gap-filling aid.

2. The method of claim 1 wherein the cured polymeric material has a glass transition temperature of at least 300° C.

3. The method of claim 1 wherein the cured polymeric material has a glass transition temperature of at least 350° C.

4. The method of claim 1 wherein the cured polymeric material has a glass transition temperature of at least 400° C.

5. The method of claim 1 wherein the cured polymeric material has a thermal stability temperature of at least 350° C.

6. The method of claim 1 wherein the aspect ratio is 10 or higher.

7. The method of claim 1 wherein the gap width is 0.2 microns or less.

8. The method of claim 1 wherein the gap-filling aid is reactive with the curable polymer.

9. The method of claim 1 wherein the gap-filling aid volatilizes and diffuses out of the curable polymer when the composition is heated.

10. The method of claim 1 wherein the gap-filling aid decomposes and the decomposition products diffuse out of the curable polymer when the composition is heated.

11. The method of any of the preceding claims wherein the curable polymer is organic.

12. The method of claim 11 wherein the organic polymer is a polyimide.

13. The method of claim 11 wherein the organic polymer is a polyarylene or polyarylene ether.

14. The method of claim 11 or claim 13 wherein the polymer has a number average molecular weight in the range of 3,000 to 10,000.

15. The method of claim 13 or 14 wherein the polymer comprises diene reactive groups, dienophile reactive groups, or both.

16. The method of claim 15 wherein the gap filling aid is a reactive monomer or reactive low molecular weight oligomer having reactive groups selected from dienes, dienophiles, and combinations thereof.

17. The method of claim 15 or 16 wherein the reactive functional groups are cyclopentadienone and acetylene groups.

18. The method of claim 17 wherein the reactive monomer comprises acetylene functional groups.

19. The method of any one of claims 1 through 11 wherein the gap filling aid is selected from reactive monomers; reactive, low molecular weight oligomers; and low molecular weight thermally transient modifiers.

20. The method of claim 19 wherein the thermally transient modifier is a polystyrene, polyacrylate, or polymethacrylate.

21. The method of any one of the preceding claims wherein the curable polymer is present in amounts of 5-40% by weight of the composition and the gap filling aid is present in an amount of 1-20% by weight of the composition.

22. The method of claim 21 wherein the curable polymer is present in an amount of 10-30% by weight of the composition, and the gap filling aid is present in an amount of 3-15% by weight of the composition.

23. The method of claim 18 wherein the reactive monomer is a tris(phenylethynyl) benzene.

24. An article made by the method of any one of claims 1-23.

25. A composition comprising (i) a curable polymeric material, (ii) a thermally deactivatable gap-filling aid, and (iii) at least one solvent.
